(19) United States
(12) Patent Application Publication
(10) Pub. No.: US 2026/0110087 A1
(43) Pub. Date: Apr. 23, 2026

(54) METHOD AND SYSTEM FOR FORMING METAL-NIOBIUM OXIDE FILM

(71) Applicant: ASM IP Holding B.V., Almere (NL)

(72) Inventors: Emre Yarali, Helsinki (FI); Ibrahim Issah, Vantaa (FI); Andrea Illiberi, Leuven (BE); Alessandra Leonhardt, Sipoo (FI); Charles Dezelah, Helsinki (FI); Lorenzo Bottiglieri, Phoenix, AZ (US); Vivek Koladi Mootheri, Leuven (BE); Mohamed Mohamed El Kordy Shehata, Leuven (BE)

(21) Appl. No.: 19/360,870

(22) Filed: Oct. 16, 2025

Related U.S. Application Data
(60) Provisional application No. 63/708,954, filed on Oct. 18, 2024.

(51) Int. Cl. C23C 16/455; C23C 16/40; C23C 16/44; C23C 16/52; H01L 21/02; H10D 1/00

(52) U.S. Cl. CPC C23C 16/45531; C23C 16/405; C23C 16/4408; C23C 16/45544; C23C 16/52; H10D 1/041; H10P 14/6339; H10P 14/6939

(57) ABSTRACT

A process for depositing a metal-niobium oxide film on a substrate using a deposition method may include a plurality of complete deposition cycles. Each complete deposition cycle may comprise performing a metal-oxidizer sub-cycle followed by a niobium sub-cycle. The metal-oxidizer sub-cycle may comprise contacting the substrate with a metal precursor and a first oxygen precursor. The niobium sub-cycle may comprise contacting the substrate with at least a niobium precursor.

### CROSS-REFERENCE TO RELATED APPLICATION(S)

This Application claims the benefit of U.S. Provisional Application 63/708,954 filed on Oct. 18, 2024, the entire contents of which are incorporated herein by reference.

### FIELD OF INVENTION

The present disclosure relates generally to the field of semiconductor device manufacturing, such as the manufacturing of capacitors in Back End of Line (BEOL) and Dynamic Random Access Memory (DRAM), and, more particularly, to the deposition of metal-niobium oxide films for use as the dielectric layer in capacitors.

### BACKGROUND OF THE DISCLOSURE

DRAM, BEOL, and other memory and/or logic devices may utilize capacitors to store bits of information. Such capacitors may be formed by placing a dielectric material between two electrodes formed of conductive materials. With reductions in device sizes and spacing, DRAM and BEOL devices often use Metal-Insulator-Metal (MIM) capacitors in which the electrode materials are metals with high conductivity to ensure fast device speeds and store the same amount of charge in the reduced dimension. However, such MIM capacitors may be strongly affected by high leakage current. Reducing the leakage current in MIM capacitors becomes a critical aspect of being able to scale down the dimensions on the insulating or dielectric layers of the MIM capacitors, thus achieving high capacitance densities. In addition, three-dimensional (3D) DRAM and/or BEOL devices will eventually need MIM capacitors comprising dielectric layers with dielectric constants greater than 50 or MIM capacitors that maintain a capacitance density of at least 100 nF/cm² even when the dimensions of the dielectric layers are reduced. Current dielectric materials used in MIM capacitors do not have such high electric constants. Moreover, some dielectric materials with high dielectric constants may suffer from high leakage currents. Thus, there is a need for improved MIM capacitors having a dielectric layer with a dielectric constant above 50 and a low leakage current. Also, there is a need for innovative manufacturing techniques that can produce such a dielectric layer with high dielectric contact and low leakage current while complying with stringent thermal budgets and remaining cost-effective for high-volume production.

### SUMMARY OF THE DISCLOSURE

This summary is provided to introduce a selection of concepts in a simplified form. These concepts are described in further detail in the detailed description of example embodiments of the disclosure below. This summary is not intended to identify key features or essential features of the claimed subject matter, nor is it intended to be used to limit the scope of the claimed subject matter.

Disclosed herein, according to various embodiments, is a method of fabricating niobium oxide containing films, which may be used as dielectric layers in MIM capacitors. Such niobium oxide containing films may have dielectric constants above 50 and low leakage currents. The method of fabricating niobium oxide containing films may comprise a plurality of complete deposition cycles. Each complete deposition cycle, of the plurality of complete deposition cycles, may comprise performing a metal-oxidizer sub-cycle and then performing a niobium sub-cycle. Performing the metal-oxidizer sub-cycle may comprise contacting the substrate with a metal precursor and a first oxygen precursor, while performing the niobium sub-cycle may comprise contacting the substrate with a niobium precursor.

In various embodiments, performing the niobium sub-cycle may further comprise contacting the substrate with the niobium precursor and the first oxygen precursor. Alternatively, or additionally, in other embodiments, performing the niobium sub-cycle may further comprise contacting the substrate with the niobium precursor and a second oxygen precursor different than the first oxygen precursor.

In various embodiments, performing the niobium sub-cycle may further comprise supplying the first oxygen precursor to the reaction chamber after completing the plurality of complete deposition cycles. Alternatively, or additionally, in other embodiments, performing the niobium sub-cycle may further comprise supplying a second oxygen precursor to the reaction chamber after completing the plurality of complete deposition cycles, where the second oxygen precursor is different than the first oxygen precursor.

In various embodiments, the method of fabricating niobium oxide containing films may further comprise removing excess precursors and reaction byproducts from the reaction chamber after contacting the substrate with the metal precursor, the first oxygen precursor, or the niobium precursor. In various embodiments, the method of fabricating niobium oxide-containing films may further comprise maintaining a deposition temperature of the reaction chamber to be less than 450° C.

In various embodiments, the metal precursor may comprise an alkali metal, an alkaline earth metal, a transition metal, a rare-earth metal, a lanthanide metal, or a post-transitional metal. In some embodiments, the metal precursor comprises bismuth, tantalum, or titanium. In some embodiments, the niobium oxide-containing film may comprise a dielectric constant between 30 and 250.

In various embodiments, the niobium oxide-containing film may comprise bismuth niobium oxide, and the metal precursor may comprise a bismuth precursor comprising at least a cyclopentadienyl ligand, an amido ligand, an imido ligand, an amidinate ligand, a halide ligand, an alkyl ligand, an alkoxide ligand, a diketonate ligand, or a diazabutadiene ligand.

In various embodiments, the niobium oxide-containing film may comprise titanium niobium oxide, and the metal precursor may comprise a titanium precursor comprising at least a cyclopentadienyl ligand, an amido ligand, an imido ligand, an amidinate ligand, a halide ligand, an alkyl ligand, an alkoxide ligand, a diketonate ligand, or a diazabutadiene ligand.

In various embodiments, the niobium oxide-containing film may comprise tantalum niobium oxide, and the metal precursor may comprise a tantalum precursor comprising at least a cyclopentadienyl ligand, an amido ligand, an imido ligand, an amidinate ligand, a halide ligand, an alkyl ligand, an alkoxide ligand, a diketonate ligand, or a diazabutadiene ligand.

In various embodiments, the first oxygen precursor and/or the second oxygen precursor may comprise one or more of molecular oxygen, ozone, hydrogen peroxide, water, formic acid, nitrous oxide, nitrogen oxide, or dinitrogen pentoxide.

In various embodiments, the niobium precursor may comprise at least a cyclopentadienyl ligand, an amido ligand, an imido ligand, an amidinate ligand, a halide ligand, an alkyl ligand, an alkoxide ligand, a diketonate ligand, or a diazabutadiene ligand.

Disclosed herein, according to various embodiments, is a reactor system for fabricating niobium oxide-containing films. The reactor system may comprise a reaction chamber for supporting a substrate, a metal source connected to the reaction chamber and configured to provide a metal precursor, a niobium source connected to the reaction chamber and configured to provide a niobium precursor, a first oxygen source connected to the reaction chamber and configured to provide a first oxygen precursor, and/or a control system configured to control the reactor to perform a plurality of complete deposition cycles to deposit a niobium oxide-containing film on the substrate. Each complete deposition cycle may comprise a metal-oxidizer sub-cycle where a metal precursor may be supplied from the metal source to the reaction chamber and the first oxygen precursor may be supplied from the first oxygen source to the reaction chamber. Each complete deposition cycle may further comprise a niobium sub-cycle where the niobium precursor from the niobium source may be supplied to the reaction chamber.

In some embodiments, the niobium sub-cycle may further comprise supplying, to the reaction chamber, the niobium precursor from the niobium source and the first oxygen precursor from the first oxygen source. In some embodiments, the reactor system may further comprise a second oxygen source connected to the reaction chamber and configured to provide a second oxygen precursor different than the first oxygen precursor, and the niobium sub-cycle may further comprise supplying, to the reaction chamber, the niobium precursor from the niobium source and the second oxygen precursor from the second oxygen source.

In some embodiments, the control system of the reactor system may be further configured to control the reactor system to supply, after completing the plurality of complete deposition cycles, the first oxygen precursor from the first oxygen source to the reaction chamber. In other embodiments, the control system may be further configured to control the reactor to supply, after completing the plurality of complete deposition cycles, the second oxygen precursor from the second oxygen source to the reaction chamber.

All of these embodiments are intended to be within the scope of the disclosure. These and other embodiments will become readily apparent to those skilled in the art from the following detailed description of certain embodiments having reference to the attached figures, the disclosure not being limited to any particular embodiment(s) discussed.

### BRIEF DESCRIPTION OF THE DRAWING FIGURES

While the specification concludes with claims particularly pointing out and distinctly claiming what are regarded as embodiments of the disclosure, the advantages of embodiments of the disclosure may be more readily ascertained from the description of certain examples of the embodiments of the disclosure when read in conjunction with the accompanying drawings. Elements with the like element numbering throughout the figures are intended to be the same.

FIG. 1 illustrates a reactor system in accordance with exemplary embodiments of the disclosure.

FIG. 2 illustrates an exemplary process flow representing an overall cyclical deposition process for forming metal-niobium oxide films in accordance with exemplary embodiments of the disclosure.

FIG. 3 illustrates another exemplary process flow representing an overall cyclical deposition process for forming metal-niobium oxide films in accordance with exemplary embodiments of the disclosure.

FIGS. 4A and 4B show experimental current-voltage (IV) characteristics and dielectric constants of bismuth tantalum niobium oxide films.

FIG. 5 illustrates a flow diagram of a method of manufacturing or fabricating a MIM capacitor with metal-niobium oxide dielectric layers in accordance with exemplary embodiments of the disclosure.

FIGS. 6A and 6B illustrate simplified cross-sectional views of portions of two example MIM capacitors fabricated in accordance with exemplary embodiments of the disclosure, such as with the method of FIG. 5.

It will be appreciated that elements in the figures are illustrated for simplicity and clarity and have not necessarily been drawn to scale. For example, the dimensions of some of the elements in the figures may be exaggerated relative to other elements to help improve understanding of illustrated embodiments of the present disclosure.

### DETAILED DESCRIPTION OF EXEMPLARY EMBODIMENTS

Although certain embodiments and examples are disclosed below, it will be understood by those in the art that the disclosure extends beyond the specifically disclosed embodiments and/or uses of the disclosure and obvious modifications and equivalents thereof. Thus, it is intended that the scope of the disclosure should not be limited by the particular embodiments described herein. The illustrations presented herein are not meant to be actual views of any particular material, apparatus, structure, or device, but are merely representations that are used to describe embodiments of the disclosure.

As used herein, “niobium oxide containing” film or “metal-niobium oxide” film may refer to a film or a layer comprising niobium atoms, oxygen atoms, and atoms of a metal other than niobium. The film or layer may have a stoichiometric composition of AₓNb_{y}O_{1-x-y}, where A may be an alkali metal, an alkaline earth metal, a transition metal, a rare-earth metal, a lanthanide metal, or a post-transitional metal.

As used herein, the term “substrate” may refer to any underlying material or materials that may be used, or upon which, a device, a circuit, or a film may be formed.

As used herein, the term “atomic layer deposition” (ALD) may refer to a vapor deposition process in which deposition cycles, preferably a plurality of consecutive deposition cycles, are conducted in a process chamber. Typically, during each deposition cycle, one or more first precursors may be chemisorbed to a deposition surface (e.g., a substrate surface or a previously deposited underlying surface such as material from a previous ALD cycle), forming a monolayer or sub-monolayer that may not readily react with additional first precursors (i.e., a self-limiting reaction). Thereafter, if necessary, one or more second precursors may subsequently be introduced into the process chamber for use in converting the chemisorbed first precursor to the desired material on the deposition surface. Typically, the second precursors may be capable of further reaction with the first precursors. Further, purging steps may also be utilized during each cycle to remove excess first or second precursors from the process chamber and/or remove excess reactants and/or reaction byproducts from the process chamber after conversion of the chemisorbed first precursors. Further, the term “atomic layer deposition,” as used herein, may also be meant to include processes designated by related terms such as “chemical vapor atomic layer deposition,” “atomic layer epitaxy” (ALE), molecular beam epitaxy (MBE), gas source MBE, or organometallic MBE, and chemical beam epitaxy when performed with alternating pulses of precursor composition(s), reactive gas, and purge (e.g., inert carrier) gas.

The term “deposition process,” as used herein, may refer to the introduction of precursors (and/or reactants) into a reaction chamber to deposit a layer over a substrate.

As used herein, the term “pulse” may refer to a procedure in which a reactive precursor or reactant is provided to a reaction chamber, for example, in between two purges, between a purge and another pulse, or between two pulses. It shall be understood that a pulse may be effected either in time, in space, or both. For example, in the case of temporal pulses, a pulse step can be used, e.g., in the temporal sequence of executing a pulse in which one or more first precursors and provided to the reaction chamber and another pulse that comprises providing one or more second precursors to the reaction chamber. In this case, the substrate on which a layer is deposited does not necessarily move during the purge-purge sequence. In some examples, the two pulses may be separated by a purging step. In the case of spatial pulses, a pulse step may take the following form: moving a substrate through a purge gas curtain to a pulse location where one or more first precursors or reactants are continually supplied and then moving the substrate through the same purge gas curtain again or another purge gas curtain where one or more second precursors or reactants are continually supplied.

As used herein, the term “purge” may refer to a procedure in which an inert or substantially inert gas may be provided to a reaction chamber in between two pulses of precursors that react with each other. For example, a purge, e.g., using a noble gas, may be provided between a first precursor pulse and a second reactant pulse, thus avoiding or at least minimizing gas phase interactions between the first precursor and the second precursor. It shall be understood that a purge can be effected either in time or in space, or both. For example, in the case of temporal purges, a purge step may be used, e.g., in the temporal sequence of providing a first precursor to a reaction chamber, providing a purge gas to the reaction chamber, and providing a second precursor to the reaction chamber, wherein the substrate on which a layer is deposited does not move. In the case of spatial purges, a purge step can take the following form: moving a substrate from a first location to which one or more first precursors are continually supplied, through a purge gas curtain, and then to a second location to which one or more second precursors are continually supplied.

“Cyclical deposition processes” are examples of “deposition processes.” The term “cyclic deposition process” or “cyclical deposition process” may refer to the sequential introduction of precursors (and/or reactants) into a reaction chamber to deposit a layer over a substrate and includes processing techniques such as atomic layer deposition (ALD), cyclical chemical vapor deposition (cyclical CVD), and hybrid cyclical deposition processes that include an ALD component and a cyclical CVD component.

As used herein, the term “sub-cycle” may refer to a cyclical deposition process comprising two or more unit cycles repeated for a predetermined number of times. This combination of two or more sub-cycles may be referred to as a complete deposition cycle.

As used herein, the terms “film” and “thin film” may refer to any continuous or non-continuous structures and material deposited by the methods disclosed herein. For example, “film” and “thin film” could include 2D materials, nanorods, nanotubes, or nanoparticles or even partial or full molecular layers or partial or full atomic layers or clusters of atoms and/or molecules. “Film” and “thin film” may comprise materials or a layer with pinholes, but still be at least partially continuous.

As used herein, the term “comprising” indicates that certain features are included but that it does not exclude the presence of other features, as long as they do not render the claim or embodiment unworkable.

A number of example materials are given throughout the embodiments of the current disclosure, and it should be noted that the chemical formulas given for each of the example materials should not be construed as limiting and that the non-limiting example materials given should not be limited by a given example stoichiometry.

The present disclosure includes methods that may be employed for the deposition of a metal-niobium oxide film by a cyclical deposition process. The cyclical deposition process may comprise a complete deposition cycle comprising at least a first sub-cycle, utilized for the deposition of metal and oxygen atoms, and a second sub-cycle, utilized for the deposition of niobium and/or oxygen atoms. The metal-niobium oxide film may be deposited by repeating the complete deposition cycle one or more times such that one or more metal oxide films and one or more niobium oxide films are deposited on the substrate. The cyclical deposition processes disclosed herein may deposit a metal-niobium oxide film with a dielectric constant above 60 and a low leakage current. In addition, the cyclical deposition processes disclosed herein may deposit a metal-niobium oxide film at a reduced deposition temperature (e.g., less than 450° C.) and with excellent conformality over substrates.

A cyclical deposition process for depositing an oxide film may comprise two or more sub-cycles, wherein each sub-cycle may comprise an ALD-type process for depositing two or more films, such as, for example, a metal oxide film and a niobium oxide film. In some embodiments, a first sub-cycle may comprise an ALD-type process for depositing a metal oxide film and one deposition cycle, e.g., a unit cycle, may comprise exposing the substrate to a vapor-phase metal precursor and a first oxygen precursor. In some embodiments, a second sub-cycle may comprise an ALD-type process for depositing a niobium oxide film and one deposition cycle, e.g., a unit cycle, may comprise exposing the substrate first to a vapor-phase niobium precursor and a second oxygen precursor. In some embodiments, the first oxygen precursor may be the same as the second oxygen precursor, while in other embodiments, the first and second oxygen precursors may be different.

In some embodiments, precursors may be separated by purging inert gases, such as argon (Ar) or nitrogen (N₂), to prevent gas-phase reactions between precursors and enable self-saturating surface reactions. In some embodiments, the substrate may be moved to separately contact different precursors. Surplus chemicals and reaction byproducts, if any, may be removed from the substrate surface, such as by purging the reaction space or by moving the substrate, before the substrate contacts the next precursor. Undesired gaseous molecules can be effectively expelled from a reaction space with the help of an inert purging gas. A vacuum pump may be used to assist in the purging. Alternatively, there may be no purging steps between pulses of precursors, and in some embodiments, precursor pulses may overlap.

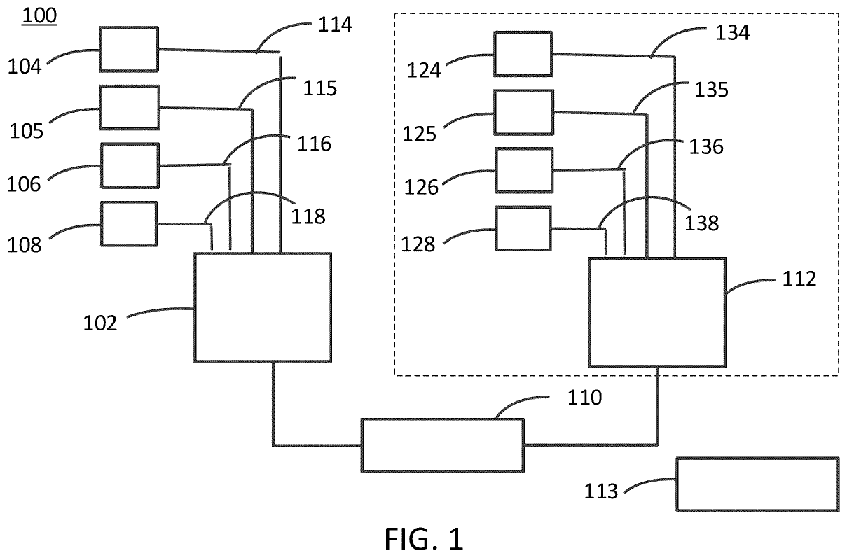

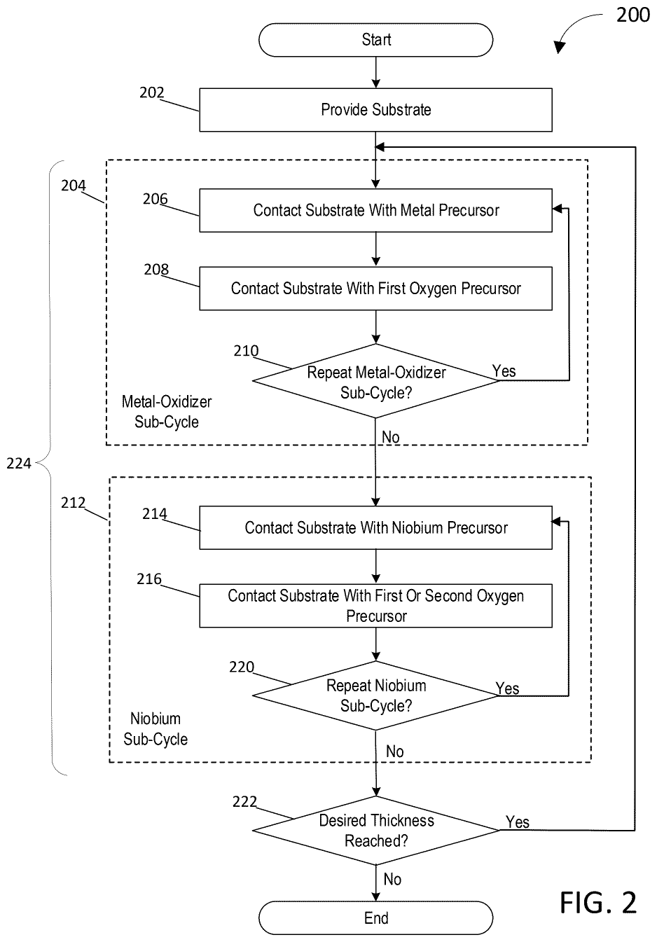

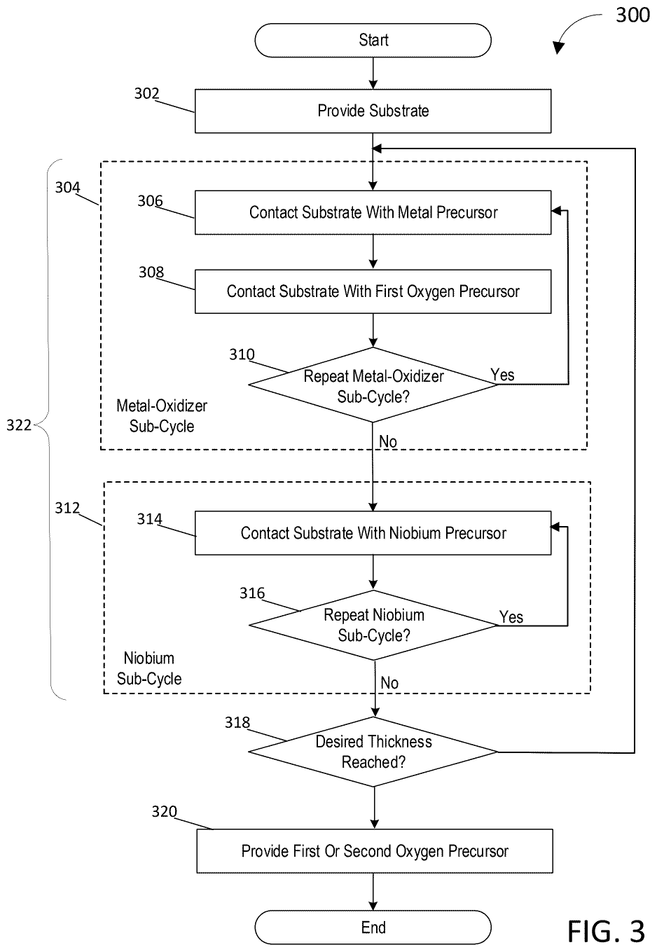

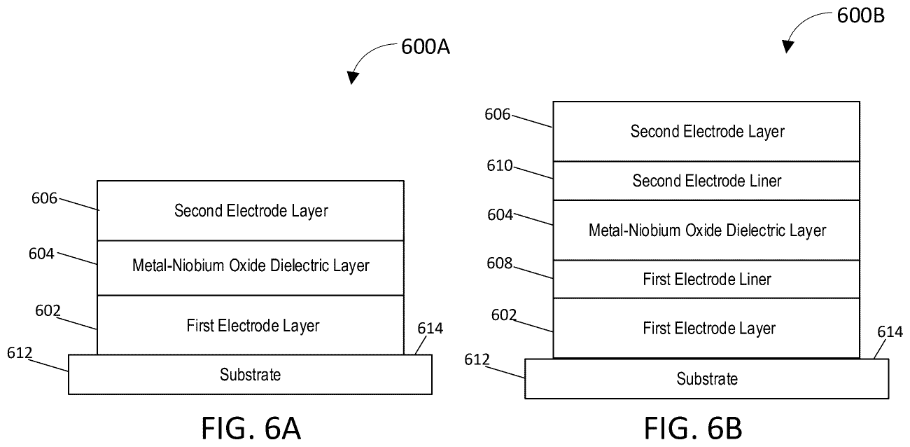

FIG. 1 illustrates a reactor system 100 that may be constructed and arranged for executing methods as described herein, such as the methods described in FIG. 2 and FIG. 3, and/or form a structure or device portion as described herein, such as the structures in FIGS. 6A and 6B. In the illustrated example, the reactor system 100 includes a reaction chamber 102, a metal precursor vessel 104, a niobium precursor vessel 105, a first oxygen precursor vessel 106, a second oxygen precursor vessel 108, an exhaust 110, and a controller 113 for forming metal-niobium oxide dielectric layers in MIM capacitors. In some embodiments, the reactor system 100 may further comprise one or more dopant precursor vessels (not shown).

The metal precursor vessel 104 may comprise a metal precursor that may be provided to the reaction chamber 102. The metal precursor may comprise an alkali metal, an alkaline earth metal, a transition metal, a rare-earth metal, a lanthanide metal, or a post-transitional metal. In various embodiments, the metal precursor may comprise bismuth (Bi), tantalum (Ta), titanium (Ti), aluminum (Al), gallium (Ga), tin (Sn), lead (Pb), indium (In), gallium (Ga), thallium (Tl), vanadium (V), chromium (Cr), manganese (Mn), iron (Fe), cobalt (Co), nickel (Ni), copper (Cu), zinc (Zn), zirconium (Zr), molybdenum (Mo), ruthenium (Ru), rhodium (Rh), silver (Ag), hafnium (Hf), tungsten (W), rhenium (Re), iridium (Ir), platinum (Pt), and/or gold (Au). The metal precursor vessel 104 may include a container and one or more metal precursors, as described herein, alone or mixed with one or more carrier (e.g., noble) gases.

In various embodiments, the reactor system 100 may be used to form a metal-niobium oxide film comprising bismuth niobium oxide. In such embodiments, the metal precursor vessel 104 may comprise a bismuth precursor. The bismuth precursor may comprise a cyclopentadienyl type ligand, an amido type ligand, an imido type ligand, an amidinate type ligand, a halide type ligand, an alkyl type ligand, an alkoxide type ligand, a diketonate type ligand, and/or a diazabutadiene type ligand.

Examples of cyclopentadienyl ligands may include cyclopentadienyl (Cp), methylcyclopentadienyl (MeCp), ethylcyclopentadienyl (EtCp), isopropylcyclopentadienyl (iPrCp), tert-butylcyclopentadienyl (tBuCp), trimethylsilylcyclopentadienyl (TMSCp), pentamethylcyclopentadientyl (Cp*), 1,2,4-triisopropylcyclopentadienyl (iPr₃Cp), and/or 1,2,4-tri-tert-butylcyclopentadienyl (tBu₃Cp). Examples of amido type ligands may include dimethylamido (NMe₂), diethylamido (NEt₂), ethylmethylamido (NEtMe), diisopropylamido (NiPr₂), tert-butylamino (NHtBu), and/or bis(trimethylsilyl)amido (N(SiMe3)₂). Examples of imido type ligands may include ethylimido (NEt), isoproptylimido (NiPr), isobutylimido (NiBu), tert-butylimido (NtBu), and/or tert-pentylimido (NtPn). Examples of amidinate type ligands may include N, N′-diethylacetamidinate (Et₂AMD), N,N′-diisopropylacetamidinate (iPr₂AMD), N,N′-diisopropylformamidinate (iPr₂FMD), N,N′-di-tert-butylacetamidinate (tBu₂AMD), and/or N,N′-di-tert-butylformamidinate (tBu₂FMD). Examples of halide ligands may include fluoro (F), chloro (Cl), bromo (Br), and/or iodo (I). Examples of alkyl ligands may include methyl (Me), ethyl (Et), isopropyl (iPr), tert-butyl (tBu), isobutyl (iBu), neopentyl (Np), phenyl (Ph), 2-[(dimethylamino)methyl]phenyl (dmamPh), and/or trimethylsilylmethyl (CH₃SiMe₃). Example alkoxide type ligands may include methoxide (OMe), ethoxide (OEt), isopropoxide (OiPr), tert-butoxide (OtBu), 1-methoxy-2-methyl-2-propoxide (mmp), 2-dimethylaminoethoxide (dmae), 1-dimethylamino-2-propoxide (dmap), 1-dimethylamino-2-methyl-2-propoxide (dmamp), 1-ethylmethylamino-2-methyl-2-propoxide (emamp), 1-diethylamino-2-methyl-2-propoxide (deamp), 1-dimethylamino-2-methyl-2-butoxide (dmamb), 1-ethylmethylamino-2-methyl-2-butoxide (emamb), and/or 1-diethylamino-2-methyl-2-butoxide (deamb), 2,3-dimethylbutoxide (dmb). Example diketonate type ligands may include acetylacetonate (acac), 2,2,6,6-tetramethylheptane-3,5-dionate (thd), and/or 1,1,1,5,5,5-hexafluoropentane-2,5-dionate (hfac). Examples of diazabutadiene type ligands may include 1,4-di-tert-butyl-1,4-diaza-1,3-butadiene (tBu₂DAD), 1,4-diisopropyl-1,4-diaza-1,3-butadiene (iPr₂DAD), 1,4-di-sec-butyl-1,4-diaza-1,3-butadiene (sBu₂DAD), and/or 1,4-di-tert-pentyl-1,4-diaza-1,3-butadiene (tPn₂DAD). In some embodiments, the bismuth precursor may be selected from the following: bismuth(III) chloride (BiCl₃), Bi(OtBu)₃, Bi(mmp)₃, Bi(dmb)₃, Bi(NMe₂)₃, Bi(NMeEt)₃, Bi[N(SiMe₃)₂]₃, Bi(thd)₃, BiMe₃, BiPh₃, BiPh₂Me, BiMe₂(dmamPh), Bi(CH₂SiMe₃)₃, Bi(OCMe₂iPr)₃), and/or Bi(CH₃)₃.

In various embodiments, the reactor system 100 may be used to form a metal-niobium oxide film comprising titanium niobium oxide. In such embodiments, the metal precursor vessel 104 may comprise a titanium precursor. The titanium precursor may comprise a cyclopentadienyl type ligand, an amido type ligand, an imido type ligand, an amidinate type ligand, a halide type ligand, an alkyl type ligand, an alkoxide type ligand, a diketonate type ligand, and/or a diazabutadiene type ligand described above. In some embodiments, the titanium precursor may be selected from the following: TiF₄, TiCl₄, TiBr₄, TiI₄, Ti(NMe₂)₄, Ti(NEtMe)₄, Ti(NEt₂)₄, Ti(OMe)₄, Ti(OEt)₄, Ti(OiPr)₄, Ti(OtBu)₄, Ti(MeCp)(OiPr)₃, TiCp*(OMe)₃, TiCp(NMe₂)₄, Ti(EtCp)(NMe₂)₄, Ta(OMe)₅, Ti(OiPr)₂(NMe₂)₂, Ti(OiPr)₂(thd)₂, Ti(OiPr)₃(iPr₂AMD), Ti(Np)₄, Ti(N(CH₃)₂)₄, Ta(NMe₂)₅, Ta(N(CH₃)₂), Ti(Np)₄, TiCp₂((iPrN)₂C(NHiPr)), Ti(Cp)CHT, Ti(CpMe₅)(OMe)₃, Ti(NEt₂)₄, -tetrakis(diethylamino)titanium, Ti(NEtMe)₃(guanNEtMe), Ti(NMe₂)₃(dmap), Ti(NMe₂)₃(CpN), Ti(OEt)₄, Ti(OiPr)₂(dmae)₂, Ti(OiPr)₂(NMe₂)₂, Ti(OiPr)₂(thd)2, and/or Ti(OiPr)₃(iPr₂AMD).

In various embodiments, the reactor system 100 may be used to form a metal-niobium oxide film comprising tantalum niobium oxide. In such embodiments, the metal precursor vessel 104 may comprise a tantalum precursor. The tantalum precursor may comprise a cyclopentadienyl type ligand, an amido type ligand, an imido type ligand, an amidinate type ligand, a halide type ligand, an alkyl type ligand, an alkoxide type ligand, a diketonate type ligand, and/or a diazabutadiene type ligand described above. In some embodiments, the tantalum precursor may be selected from the following: TaF₅, TaCl₅, TaBr₅, TaI₅, Ta(NMe₂)₅, Ta(NEt₂)₅, Ta(NEtMe)₅, Ta(NtBu)(NMe₂)₃, Ta(NtBu)(NEt₂)₃, Ta(NtBu)(NEtMe)₃, Ta(NiPr) (NEtMe)₃, Ta(NtPn)(NMe₂)₃, Ta(OEt)₅, TaNp₃Cl₂, Ta(NtBu)Cl3, Ta(NtPn)Cl₃, Ta(NtBu)(iPr₂AMD)₂(NMe₂), (CH₃O)₅Ta, (CH₃CH₂O)₅Ta, Ta(OEt)₄(dmae), and/or TaNp₃Cl₂.

Referring back to FIG. 1, the niobium precursor vessel 105 may comprise a niobium precursor that may be provided to the reaction chamber 102. The niobium precursor may comprise a cyclopentadienyl type ligand, an amido type ligand, an imido type ligand, an amidinate type ligand, a halide type ligand, an alkyl type ligand, an alkoxide type ligand, a diketonate type ligand, and/or a diazabutadiene type ligand described above. In some embodiments, the niobium precursor may be selected from the following: NbF₅, NbCl₅, NbBr₅, NbI₅, Nb(OMe)₅, Nb(OEt)₅, Nb(OiPr)₅, Nb(OtBu)₅, Nb(NMe₂)₅, Nb(NEtMe)₅, Nb(NEt₂)₅, Nb(NtBu)(NMe₂)₂(Cp), Nb(NtBu)(NEtMe)₂(Cp), Nb(NtBu)(NEt2)₂(Cp), Nb(NtBu)(NMe₂)₃, Nb(NtBu) (NEtMe)₃, Nb(NtBu)(NEt₂)₃, Nb(NiPr)(NMe₂)₃, Nb(NiPr)(NEtMe)₃, Nb(NiPr) (NEt₂)₃, Nb(NtPn)(NMe₂)₃, Nb(NtPn)(NEtMe)₃, and/or Nb(NtPn)(NEt₂)₃. The niobium precursor vessel 105 may include a container and one or more niobium precursors, as described herein, alone or mixed with one or more carrier (e.g., noble) gases.

The first oxygen precursor vessel 106 may comprise a first oxygen precursor that may be provided to the reaction chamber 102. The second oxygen precursor vessel 108 may comprise a second oxygen precursor that may be provided to the reaction chamber 102. The first oxygen precursor and/or the second oxygen precursor may comprise molecular oxygen (O₂), ozone (O₃), hydrogen peroxide (H₂O₂), water (H₂O), formic acid (HCOOH), Nitrous oxide (N₂O), nitrogen oxide (NO₂), dinitrogen pentoxide (N₂O₅), dinitrogen tetroxide (N₂O₄), pyridine N-oxide (C₅H₅NO), and/or oxygen plasma. The first oxygen precursor vessel 106 and/or the second oxygen precursor vessel 108 may include a container and one or more oxygen precursors, as described herein, alone or mixed with one or more carrier (e.g., noble) gases.

In some embodiments, the reactor system 100 may include an optional second set of one or more reaction chambers 112, which may be constructed and arranged for forming one or more electrode layers of MIM capacitors. One or more reaction chambers 112 may be operationally coupled to a first metal precursor vessel 124, an optional second metal precursor vessel 125, a reactant vessel 126, and an optional reactant vessel 128. The reaction chambers 102 and 112 may include an ALD reaction chamber.

Although illustrated with eight vessels 104, 105, 106, 108, 124, 125, 126, and 128, the reactor system 100 may include any suitable number of vessels. The vessels 104, 105, 106, 108, 124, 125, 126, and 128 may be coupled to one or more reaction chambers 102, 112 via lines 114, 115, 116, 118, 134, 135, 136, and 138, which can each include flow controllers, valves, heaters, and the like. The exhaust 110 may include one or more vacuum pumps. The exhaust may be connected to one or more of the reaction chambers 102 and 112 via one or more lines.

In some embodiments, the reaction chamber 102 may be further configured for forming dielectric layers in MIM capacitors where the dielectric layers comprise a metal-niobium oxide layer. The metal-niobium oxide layer may be a ternary compound comprising niobium atoms, oxygen atoms, and atoms of another metal other than niobium. Examples of such niobium oxide containing layers may include layers of bismuth niobium oxide (BiₓNb_{y}O_{1-x-y}), titanium niobium oxide (TiₓNb_{y}O_{1-x-y}), tantalum niobium oxide (TaₓNb_{y}O_{1-x-y}), hafnium niobium oxide (HfₓNb_{y}O_{1-x-y}), aluminum niobium oxide (AlₓNb_{y}O_{1-x-y}), tin niobium oxide (TiₓNb_{y}O_{1-x-y}), or the like.

The controller 113 may include electronic circuitry and software to selectively operate valves, manifolds, heaters, pumps and other components included in the reactor system 100. Such circuitry and components may operate to introduce precursors, reactants and purge gases from the respective vessels 104, 105, 106, 108, 124, 125, 126, 128. For example, the controller 113 may control the flow of the metal precursor in the metal precursor vessel 104 to the reaction chamber 102, the flow of the niobium precursor from the niobium precursor vessel 105 to the reaction chamber 102, the flow of the first oxygen precursor from the first oxygen precursor vessel 106 to the reaction chamber 102, and/or the flow of the second oxygen precursor from the second oxygen precursor vessel 108 to the reaction chamber 102.

The controller 113 may control the timing of precursor pulses (e.g., the pulse for the metal precursor, the pulse for the niobium precursor, the pulse for the first oxygen precursor, the pulse for the second oxygen precursor, etc.), the temperatures of the substrates and/or reaction chambers, the pressure within the reaction chambers, and various other operations to provide proper operation of the reactor system 100. The controller 113 may include control software to electrically or mechanically control valves to control the flow of precursors, reactants, and purge gases into and out of the reaction chambers 102, 112. The controller 113 may include modules such as a software or hardware component, e.g., an FPGA or ASIC, which performs certain tasks. A module can advantageously be configured to reside on the addressable storage medium of the control system and be configured to execute one or more processes as described herein.

Other configurations of the reactor system 100 may be possible, including different numbers and kinds of precursor and oxygen reactant sources and optionally further including purge gas vessels. Further, it will be appreciated that there are many arrangements of valves, conduits, precursor vessels, and purge gas vessels that may be used to accomplish the goal of selectively feeding gases into the reaction chambers 102, 112. Further, as a schematic representation of a system, many components have been omitted for simplicity of illustration, and such components may include, for example, various valves, manifolds, purifiers, heaters, containers, vents, and/or bypasses.

During operation of the reactor system 100, substrates, such as semiconductor wafers (not illustrated), are transferred from, e.g., a substrate handling system to the reaction chambers 102, 112. Once the substrate(s) are transferred to the reaction chambers 102, 112, one or more precursors from the vessels 104, 105, 106, 108, 124, 125, 126, 128, such as precursors, reactants, carrier gases, and/or purge gases, are introduced into the reaction chambers 102, 112. In some embodiments of the disclosure, the reactor system 100 may be a batch reactor. In some embodiments, the reactor system 100 may be a vertical batch reactor. In other embodiments, the reactor system 100 may comprise a mini-batch reactor configured to accommodate 10 or fewer substrates, 8 or fewer substrates, 6 or fewer substrates, 4 or fewer substrates, or 2 or fewer substrates.

In some embodiments of the disclosure, a cyclical deposition process may be utilized to deposit an oxide film, such as, for example, a metal-niobium oxide film comprising a metal component, a niobium component, and an oxygen component. Non-limiting examples of such cyclical deposition processes may be understood with reference to FIGS. 2 and 3.

FIG. 2 shows a flow chart of an example of a process 200 for forming a metal-niobium oxide film on a substrate. In some embodiments, the process 200 may be a thermal ALD process or a plasma-enhanced ALD process. The process 200 may start at step 202, which may involve providing a substrate in a reaction chamber (e.g., the reaction chamber 102). In some embodiments, the process 200 may be performed at a deposition temperature of less than 450° C., for example, at a deposition temperature in the range of 200° C. to 300° C.

The process 200 can include one or more complete deposition cycles 224, where each complete deposition cycle comprises a metal-oxidizer sub-cycle 204 and/or a niobium sub-cycle 212. In some embodiments, the metal-oxidizer sub-cycle 204, the niobium sub-cycle 212, and/or the complete deposition cycle 224 can be repeated a number of times to form the metal-niobium oxide film having a desired composition and/or thickness. The ratio of the number of times of performing the metal-oxidizer sub-cycle 204 to the niobium sub-cycle 212 may be varied to tune the stoichiometric concentration of the metal and/or the stoichiometric concentration of niobium in the metal-niobium oxide film for achieving a film with desired electrical characteristics.

The metal-oxidizer sub-cycle 204 may include steps 206, 208, and 210. At step 206, the substrate may be contacted with or exposed to a metal precursor. The metal precursor may comprise metal precursors available from the metal precursor vessel 104. At step 208, the substrate can be contacted with or exposed to a first oxygen precursor. The first oxygen precursor may comprise oxygen precursors available from the first oxygen precursor vessel 106. In some embodiments, the metal-oxidizer sub-cycle 204 can be repeated a number of times before proceeding to the niobium sub-cycle 212. In some embodiments, the metal-oxidizer sub-cycle 204 or the niobium sub-cycle 212 may be repeated a number of times before performing one or more times the other sub-cycle. For example, the metal-oxidizer sub-cycle 204 may be repeated a number of times before performing the niobium sub-cycle 212. At step 210, it may be determined whether the metal-oxidizer sub-cycle 204 needs to be repeated. If the metal-oxidizer sub-cycle 204 needs to be repeated (step 210: YES), the process 200 may proceed to step 206. Otherwise (step 210: NO), the process 200 may proceed to the niobium sub-cycle 212.

In some embodiments, pulses of the metal precursor for exposing the substrate to the metal precursor and pulses of the first oxygen precursor for exposing the substrate to the first oxygen precursor may partially overlap. In some embodiments, a pulse of the metal precursor may be immediately followed by a pulse of the first oxygen precursor. In some embodiments, the pulse of the metal precursor and the pulse of the first oxygen precursor may be separated by a purging step of removing excess metal precursor or excess first oxygen precursors from the reaction chamber. In some embodiments, the metal-oxidizer sub-cycle 204 may be an ALD process. In some embodiments, no additional precursors may be provided to the reaction chamber either between steps 206 and 208, or before starting steps 206 and 208.

The niobium sub-cycle 212 for introducing a niobium component into the metal-niobium oxide film may include steps 214 and 216. At step 214, the substrate can be contacted with or exposed to a niobium precursor. The niobium precursor may comprise niobium precursors available from the niobium precursor vessel 105. At step 216, the substrate may be contacted with or be exposed to the first oxygen precursor of step 208 or a second oxygen precursor. The first oxygen precursor may comprise the first oxygen precursors available from the first oxygen precursor vessel 106. The second oxygen precursor may comprise second oxygen precursors available from the second oxygen precursor vessel 108. In some embodiments, the first oxygen precursor may be different from the second oxygen precursor. For example, the first oxygen precursor may comprise water, while the second oxygen precursor may comprise ozone.

In some embodiments, the niobium sub-cycle 212 may be repeated a number of times. At step 220, it may be determined whether the niobium sub-cycle 212 needs to be repeated. If the niobium sub-cycle 212 needs to be repeated (step 220: YES), the process 200 may proceed to step 214. Otherwise (step 220: NO), the process 200 proceeds to the decision gate 222.

In some embodiments, pulses of the niobium precursor and pulses of the first or second oxygen precursor may partially overlap. In some embodiments, a pulse of the niobium precursor may be immediately followed by a pulse of the first or second oxygen precursor. In some embodiments, the pulse of the niobium precursor and the pulse of the first or second oxygen precursor may be separated by a purging step of removing excess niobium precursor or excess first or second oxygen precursors from the reaction chamber. In some embodiments, the niobium sub-cycle 212 may be an ALD process. In some embodiments, no additional precursors may be provided to the reaction chamber either between steps 214 and 216, or before starting steps 214 and 216.

In some examples, the process 200 may comprise repeating the complete deposition cycle 224 one or more times. For example, after finishing a niobium sub-cycle 212, the process 200 may continue with the decision gate 222 which determines if the process 200 continues or exits. The decision gate 222 may be determined based on the thickness of the metal-niobium oxide film deposited; for example, if the thickness of the film is insufficient (step 222: YES), then the process may return to step 206 of the metal-oxidizer sub-cycle 204. Before returning to step 206, in some examples, the reaction chamber may be purged with one or more purging gasses (e.g., inert gasses). In other examples, purging may be skipped. Purging the reaction chamber may remove any excess precursor from the process chamber and/or remove any excess reactant, radicals, ions, and/or reaction byproducts from the reaction chamber. If it is determined at the decision gate 222 that the thickness of the metal-niobium oxide film is sufficient (step 222: NO), the process 200 may exit.

The pulse length for a metal precursor pulse (e.g., for the metal-oxidizer sub-cycle 204), a first oxygen precursor pulse (e.g., for the metal-oxidizer sub-cycle 204 or the niobium sub-cycle 212), a niobium precursor pulse (e.g., for the niobium sub-cycle 212), and/or a second oxygen precursor pulse (e.g., for the niobium sub-cycle 212) may be from about 0.05 seconds to about 5.0 seconds, including about 0.1 seconds to about 3 seconds, and about 0.2 seconds to about 1.0 second. In some embodiments, the pulse length for one or more of the precursors may be the same or different.

FIG. 3 shows a flow chart of an example of another process 300 for forming a metal-niobium oxide film on a substrate. In some embodiments, the process 300 may be a thermal ALD process or a plasma-enhanced ALD process. The process 300 may start at step 302, which may involve providing a substrate in a reaction chamber (e.g., the reaction chamber 102). In some embodiments, the process 300 may be performed at a deposition temperature of less than 450° C., for example, at a deposition temperature in the range of 200° C. to 300° C.

The process 300 can include one or more complete deposition cycles 322, where each complete deposition cycle comprises a metal-oxidizer sub-cycle 304 and/or a niobium sub-cycle 312. In some embodiments, the metal-oxidizer sub-cycle 304, the niobium sub-cycle 312, and/or the complete deposition cycle 322 can be repeated a number of times to form a metal-niobium oxide film having a desired composition and/or thickness. The ratio of the number of times performing the metal-oxidizer sub-cycle 204 to the niobium sub-cycle 212 may be varied to tune the stoichiometric concentration of the metal and/or the stoichiometric concentration of niobium metal in the metal-niobium oxide film to achieve a film with desired electrical characteristics.

The metal-oxidizer sub-cycle 304 may include steps 306, 308, and 310. At step 306, the substrate may be contacted with or exposed to a metal precursor. The metal precursor may comprise metal precursors available from the metal precursor vessel 104. At step 308, the substrate can be contacted with or exposed to a first oxygen precursor. The first oxygen precursor may comprise oxygen precursors available from the first oxygen precursor vessel 106. In some embodiments, the metal-oxidizer sub-cycle 304 can be repeated a number of times before proceeding to the niobium sub-cycle 312. In some embodiments, the metal-oxidizer sub-cycle 304 or the niobium sub-cycle 312 may be repeated a number of times before performing the other sub-cycle one or more times. For example, the metal-oxidizer sub-cycle 304 may be repeated a number of times before performing the niobium sub-cycle 312. At step 310, it may be determined whether the metal-oxidizer sub-cycle 304 needs to be repeated. If the metal-oxidizer sub-cycle 304 needs to be repeated (step 310: YES), the process 300 may proceed to step 306. Otherwise (step 310: NO), the process 300 proceeds to the niobium sub-cycle 312.

In some embodiments, pulses of the metal precursor for exposing the substrate to the metal precursor and pulses of the first oxygen precursor for exposing the substrate to the first oxygen precursor may partially overlap. In some embodiments, a pulse of the metal precursor may be immediately followed by a pulse of the first oxygen precursor. In some embodiments, the pulse of the metal precursor and the pulse of the first oxygen precursor may be separated by a purging step of removing excess metal precursor or excess first oxygen precursors from the reaction chamber. In some embodiments, the metal-oxidizer sub-cycle 304 may be an ALD process. In some embodiments, no additional precursors may be provided to the reaction chamber either between steps 306 and 308, or before starting steps 306 and 308.

The niobium sub-cycle 312 for introducing a niobium component into the metal-niobium oxide film may include step 314. At step 314, the substrate can be contacted with or exposed to a niobium precursor. The niobium precursor may comprise niobium precursors available from the niobium precursor vessel 105.

In some embodiments, the niobium sub-cycle 312 may be repeated a number of times. At step 316, it may be determined whether the niobium sub-cycle 212 needs to be repeated. If the niobium sub-cycle 212 needs to be repeated (step 316: YES), the process 300 may proceed to step 314. Otherwise (step 316: NO), the process 300 proceeds to the decision gate 318.

In some embodiments, pulses of the niobium precursor and pulses of the first or second oxygen precursor in the process 300 may partially overlap. In some embodiments, a pulse of the niobium precursor in the process 300 may be immediately followed by a pulse of the first or second oxygen precursor. In some embodiments, the pulse of the niobium precursor and the pulse of the first or second oxygen precursor in the process 300 may be separated by a purging step of removing excess niobium precursor or excess first or second oxygen precursors from the reaction chamber. In some embodiments, the niobium sub-cycle 312 may be an ALD process. In some embodiments, no additional precursors may be provided to the reaction chamber before starting step 314.

In some examples, the process 300 may comprise repeating the complete deposition cycle 322 one or more times. For example, after finishing a niobium sub-cycle 312, the process 300 may continue with the decision gate 318, which determines if the process 300 continues or exits. The decision gate 318 may be determined based on the thickness of the metal-niobium oxide film deposited; for example, if the thickness of the film is insufficient (step 318: YES), then the process may return to step 306 of the metal-oxidizer sub-cycle 304. Before returning to step 306, in some examples, the reaction chamber may be purged with one or more purging gasses (e.g., inert gasses). In other examples, purging may be skipped. If at the decision gate 318, it is determined that the thickness of the metal-niobium oxide film is sufficient (step 318: NO), the process 300 may proceed to step 320.

At step 320, the first oxygen precursor of step 308 or a second oxygen precursor may be provided inside the reaction chamber. Oxygen atoms from the first or second oxygen precursor may fill up holes and/or defects in the metal-niobium oxide film formed via the one or more complete deposition cycles 322. The first oxygen precursor may comprise the first oxygen precursors available from the first oxygen precursor vessel 106. The second oxygen precursor may comprise second oxygen precursors available from the second oxygen precursor vessel 108. In some embodiments, the first oxygen precursor may be different from the second oxygen precursor. For example, the first oxygen precursor may comprise water, while the second oxygen precursor may comprise ozone.

The pulse length for a metal precursor pulse (e.g., for the metal-oxidizer sub-cycle 304), a first oxygen precursor pulse (e.g., for the metal-oxidizer sub-cycle 304), and/or a niobium precursor pulse (e.g., for the niobium sub-cycle 312), may be from about 0.05 seconds to about 5.0 seconds, including about 0.1 seconds to about 3 seconds, and about 0.2 seconds to about 1.0 second. In some embodiments, the pulse length for the one or more of the precursors may be the same or different. In some embodiments, the first oxygen precursor pulse or the second oxygen precursor pulse at step 320 may be longer than the precursor pulses for the metal-oxidizer sub-cycle 304 and the niobium sub-cycle 312.

In some embodiments, a precursor pulse for delivering one or more precursors into a reaction chamber in an ALD process can be followed by a removal process, such as for the removal of excess precursors and/or reaction byproducts from the vicinity of the substrate surface. The removal process may include evacuating reaction byproducts and/or excess reactants between precursor pulses, for example, by drawing a vacuum on the reaction chamber to evacuate excess reactants and/or reaction byproducts. In some embodiments, the removal process includes a purge process. A gas such as nitrogen (N2), argon (Ar) and/or helium (He) can be used as a purge gas to aid in the removal of the excess reactants and/or reaction byproducts. In some embodiments, a purge pulse may have a pulse length of about 1 second to about 20 seconds.

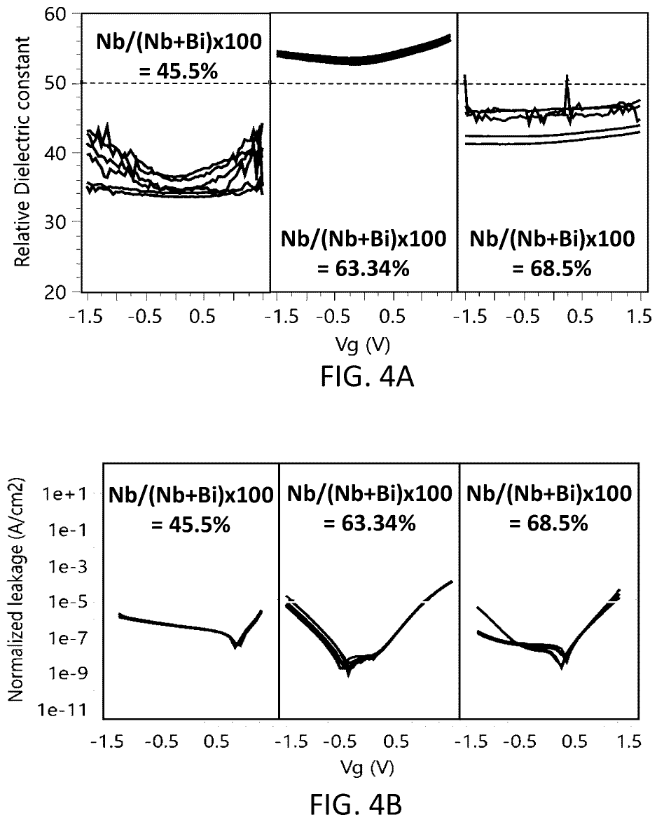

The stoichiometry ratio of niobium and metal in a metal-niobium oxide film may strongly impact the dielectric constant of the metal-niobium oxide film. Different stoichiometry ratios may result in the formation of different crystallographic phases and lead to different dielectric properties, energy gaps, and leakage currents. Stoichiometry ratios may be controlled during ALD processes to fine tune the properties of the metal-niobium oxide films. For example, FIG. 4A shows the experimental dielectric constants of bismuth niobium oxide (BiNbO) films with three different stoichiometry ratios of bismuth and niobium in capacitors comprising one titanium nitride electrode and one palladium electrode. Furthermore, a ruthenium liner is sandwiched between the titanium nitride electrode and the bismuth niobium oxide film, and another ruthenium liner is sandwiched between the palladium electrode and the bismuth niobium oxide film FIG. 4B shows the obtained leakage currents for the different stoichiometry ratios. As seen in FIG. 4A, the dielectric constants of bismuth niobium oxide films may be fine-tuned by controlling the stoichiometry ratios of bismuth and niobium. For example, 63.34% niobium and 36.66% tantalum may result in a dielectric contact above 50. As shown in FIG. 4B, the leakage current of bismuth niobium oxide also varies with the stoichiometry ratios of bismuth and niobium. For example, bismuth niobium oxide with 63.34% niobium and 36.66% bismuth tantalum may result in a leakage current of 10-9/cm2 ampere when a voltage of 1 volt/meter is applied.

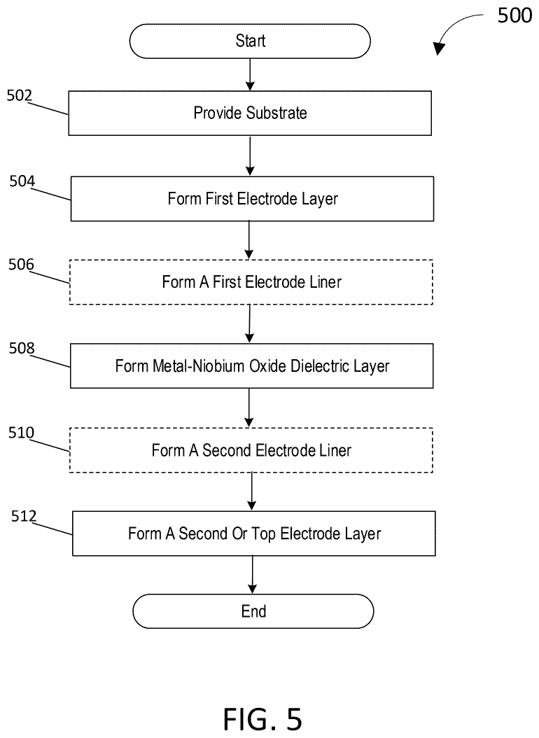

FIG. 5 illustrates a flow diagram of a method 500 of manufacturing or fabricating a MIM capacitor or a capacitor stack comprising a metal-niobium oxide dielectric layer in accordance with exemplary embodiments of the disclosure. The metal-niobium oxide dielectric layer may be positioned between two metal electrodes and/or be in direct contact with the two metal electrodes. However, metal electrodes of a MIM capacitor may contribute to high leakage current, and therefore, a metal liner may be sandwiched between an electrode and the dielectric layer of the MIM capacitor. The noble metal liner may be formed using ALD or another deposition process and be formed of a material chosen due to having a high work function, such as iridium (Ir), ruthenium (Ru), platinum (Pt), or other noble metal. The electrodes of the MIM capacitor may be formed of titanium nitride (TiN) or another metal useful in a MIM capacitor, while the dielectric layer may comprise a metal-niobium oxide film (e.g., bismuth niobium oxide (BiₓNb_{y}O_{1-x-y}), titanium niobium oxide (TiₓNb_{y}O_{1-x-y}), tantalum niobium oxide (TaₓNb_{y}O_{1-x-y}), hafnium niobium oxide (HfₓNb_{y}O_{1-x-y}), aluminum niobium oxide (AlₓNb_{y}O_{1-x-y}), tin niobium oxide (TiₓNb_{y}O_{1-x-y}), or the like). The metal liner may be provided at a thickness of less than or equal to 5 nm, such as between about 0.5 nm and about 5 nm, which may be adequate to cap the electrode layers.

Each of the layers in a MIM capacitor or capacitor stack may be formed using any common formation techniques such as ALD (or ALD-like process or other cyclical deposition processes), PVD, or CVD that are useful for deposition of thin films or layers of materials described herein. Hence, the method 500 may be intended to include any useful process for depositing the layers or thin films of the MIM capacitor or capacitor stacks shown in FIGS. 6A and 6B. The initial step 502 may involve providing in a reaction chamber a substrate, which may have already received several processing steps useful in the manufacture of a full DRAM, BEOL, or other electronic device and may take the form of a silicon wafer or other useful substrate material(s).

At step 504, a first electrode layer may be formed above or on an upper surface of the substrate from step 502. In some embodiments, the first electrode layer may be formed by depositing a thin film of a metal (such as titanium nitride (TiN)) through one of the deposition processes described above. The metal layer or element providing the first electrode layer may be formed of other metals, conductive metal oxides, conductive metal silicides, conductive metal nitrides, and combinations thereof. The purpose of the first electrode in a MIM capacitor or another device may be to serve as a primary conductor.

Step 506 of method 500 may be optional and may be skipped to form MIM capacitors without electrode liners. Step 506 may include forming a thin layer or film that acts as a first electrode liner for the first electrode formed in step 504. Step 506 may involve depositing, with PVD, ALD, or another useful deposition technology, a layer or film of a noble metal over the upper or exposed surface of the first electrode layer from step 504. In some implementations of the method 500, step 506 of forming the first electrode liner (and/or step 510 of forming the second electrode liner) may be performed using a cyclical deposition process including a plurality of cycles (e.g., ALD, an ALD-like process, or the like). The first electrode liner (and/or the second electrode liner) may comprise alloys, stacks, nanolaminates, or combinations thereof, including one or more noble metals, such as rhenium, ruthenium, rhodium, palladium, silver, osmium, iridium, platinum, and gold. The first electrode liner (and/or the second electrode liner) may have a thickness less than or equal to 5 nm. A variety of noble metals may be deposited at step 504 to form the first electrode liner. In some embodiments, a noble metal may be selected with a work function greater than about 5 eV.

At step 508, a metal-niobium oxide dielectric layer may be formed on or over the exposed upper surface of the first electrode liner formed in step 506 or the first electrode layer in step 504. The metal-niobium oxide dielectric layer 604 may be formed by the deposition methods described in FIGS. 2 and 3 of the disclosure. The metal-niobium oxide dielectric layer 604 may comprise AₓNb_{y}O_{1-x-y}, where A may be an alkali metal, an alkaline earth metal, a transition metal, a rare-earth metal, a lanthanide metal, an actinide metal, or a post-transitional metal. Non-limiting examples of materials for the metal-niobium oxide dielectric layer may comprise bismuth niobium oxide (BiₓNb_{y}O_{1-x-y}), titanium niobium oxide (TiₓNb_{y}O_{1-x-y}), tantalum niobium oxide (TaₓNb_{y}O_{1-x-y}), hafnium niobium oxide (HfₓNb_{y}O_{1-x-y}), aluminum niobium oxide (AlₓNb_{y}O_{1-x-y}), tin niobium oxide (TiₓNb_{y}O_{1-x-y}), or the like. The metal-niobium oxide dielectric layer may comprise a thickness in the range of 1 to 50 nm.

Next, step 510 of method 500 includes forming a thin layer or film that acts as a second electrode liner for a second electrode layer to be later formed in step 512. As discussed above, step 510, similar to step 506, may be optional and may be skipped to form MIM capacitors without electrode liners. Step 510 may involve depositing, with PVD, ALD, or another useful deposition technology, a layer or film of a noble metal over the upper or exposed surface of the dielectric layer from step 508. As with the first electrode liner formed in step 506, the second electrode liner may have a thickness less than or equal to 5 nm. The thickness of the second electrode liner formed in step 510 may be equal to or different from that of the first electrode liner formed in step 506. A variety of noble metals may be deposited in step 510 to form the second electrode liner, and the same noble metal may be used for the first and second electrode liners, or the noble material may differ to suit a particular MIM capacitor design.

At step 512, a second electrode layer may be formed above or on the upper surface of the second electrode liner from step 510 or the metal-niobium oxide dielectric layer from step 508. In one embodiment, the second electrode layer may be formed by depositing a thin film of a metal (such as titanium nitride (TiN)) through one of the deposition processes described above. The method 500 may include additional steps (not shown). For example, in the case of etching the electrodes, the electrode conductive material (e.g., a metal) can be etched as usual, i.e., using an etch chemistry adapted for etching the bulk electrode, and the liner can act as an etch stop layer. Then, a short and different etch cycle may be used to punch through the liner as part of the capacitor fabrication.

FIG. 6A illustrates a simplified cross-sectional view of a portion of a MIM capacitor or capacitor stack 600A fabricated in accordance with some embodiments of the present disclosure, such as with steps 502, 504, 508, and 512 of the method 500 of FIG. 5. As shown, a first electrode layer 602 may be formed above a substrate 612. The first electrode layer 602 may comprise a metal (or other conductive material) film or layer (e.g., a thickness of TiN or other conductive materials useful in forming capacitor electrodes) that may be deposited upon the upper surface 614 of the substrate 612, such that lower side or surface of the first electrode layer 602 may abut or be in contact with the upper surface 614 of the substrate 612.

A metal-niobium oxide dielectric layer 604 may be provided or deposited on the upper side or surface of the first electrode layer 602 such that the lower side or surface of the metal-niobium oxide dielectric layer 604 is in contact with or abuts the first electrode layer 602. The metal-niobium oxide dielectric layer 604 may comprise bismuth niobium oxide (BiₓNb_{y}O_{1-x-y}), titanium niobium oxide (TiₓNb_{y}O_{1-x-y}), tantalum niobium oxide (TaₓNb_{y}O_{1-x-y}), hafnium niobium oxide (HfₓNb_{y}O_{1-x-y}), aluminum niobium oxide (AlₓNb_{y}O_{1-x-y}), tin niobium oxide (TiₓNb_{y}O_{1-x-y}), or the like. The metal-niobium oxide dielectric layer 604 may be formed by the deposition methods described in FIGS. 2 and 3 of the disclosure.

The MIM capacitor or capacitor stack 600A may further include a second electrode layer 606 that may be formed of a thin film or layer of a conductive material (such as TiN or another useful conductive material or metal, as discussed above). The second electrode layer 606 may be formed of the same metal as that of the first electrode layer 602 or may be formed of a different metal to suit a particular MIM capacitor design. Likewise, the thicknesses of the first electrode layer 602 and the second electrode layer 606 may be equal (or substantially so) or different. The second electrode layer 606 may be deposited with its lower surface or side abutting or being in contact with the upper surface or side of the metal-niobium oxide dielectric layer 604.

FIG. 6B illustrates a simplified cross-sectional view of a portion of a MIM capacitor or capacitor stack 600B fabricated in accordance with some embodiments of the present disclosure, such as with steps 502, 504, 506, 508, 510, and 512 of the method 500 of FIG. 5A. As shown, a first electrode layer 602 may be formed above a substrate 612, where the first electrode layer 602 may comprise a metal (or other conductive material) film or layer.

A layer of noble metal may be deposited to form a first electrode liner 608 over the first electrode layer 602. The first electrode liner 608 may be formed of iridium (Ir), ruthenium (Ru), platinum (Pt), or other noble metals. The first electrode liner 608 may comprise a thickness of less than or equal to 5 nm, such as in the range of 0.5 to 5 nm, and may be formed to provide a cap over the first electrode layer 602 with the lower surface of the first electrode liner 608 covering the upper side or surface of the first electrode layer 602.

The stack 600B may further include a metal-niobium oxide dielectric layer 604 that may be provided or deposited on the upper side or surface of the first electrode liner 602 such that the upper side or surface of the first electrode liner 608 may be in contact with or abutting the metal-niobium oxide dielectric layer 604. Stated differently, the first electrode liner 608 may be sandwiched, in the capacitor stack 600B, between the first electrode layer 602 and the metal-niobium oxide dielectric layer 604. The metal-niobium oxide dielectric layer 604 may be formed by the deposition methods described in FIGS. 2 and 3 of the disclosure. The metal-niobium oxide dielectric layer 604 may comprise bismuth niobium oxide (BiₓNb_{y}O_{1-x-y}), titanium niobium oxide (TiₓNb_{y}O_{1-x-y}), tantalum niobium oxide (TaₓNb_{y}O_{1-x-y}), hafnium niobium oxide (HfₓNb_{y}O_{1-x-y}), aluminum niobium oxide (AlₓNb_{y}O_{1-x-y}), tin niobium oxide (TiₓNb_{y}O_{1-x-y}), or the like.

A second electrode liner 610 may be formed over the metal-niobium oxide dielectric layer 604 to provide a cap or barrier for the second electrode layer 606. The second electrode liner 610 may be formed of iridium (Ir), ruthenium (Ru), platinum (Pt), or other noble metal. The second electrode liner 610 may have a thickness of less than or equal to 5 nm, such as in the range of 0.5 to 5 nm, and may be formed with the lower surface of the second electrode liner 610 covering the upper side or surface of the metal-niobium oxide dielectric layer 604. The second electrode liner 610 may be formed of the same noble metal as the first electrode liner 608 with matching or nearly matching thicknesses. Alternatively, the second electrode liner 610 may be formed of a different noble metal than the first electrode liner 608, and/or the second electrode liner 610 and the first electrode liner 608 may have different thicknesses.

The MIM capacitor or capacitor stack 600B may further include a second electrode layer 606 that may be formed of a thin film or layer of a conductive material (such as TiN or another useful conductive material or metal, as discussed above). The second electrode layer 606 may be formed of the same metal as that of the first electrode layer 602 or may be formed of a differing metal to suit a particular MIM capacitor design. Likewise, the thicknesses of the first electrode layer 602 and the second electrode layer 606 may be equal (or substantially so) or be different. The second electrode layer 606 may be deposited with its lower surface or side abutting or being in contact with the upper surface or side of the second electrode liner 610, whereby the second electrode liner 610 caps the second electrode layer 606.

Benefits, other advantages, and solutions to problems have been described herein with regard to specific embodiments. However, the benefits, advantages, solutions to problems, and any elements that may cause any benefit, advantage, or solution to occur or become more pronounced are not to be construed as critical, required, or essential features or elements of the disclosure.

Reference throughout this specification to features, advantages, or similar language does not imply that all of the features and advantages that may be realized with the present disclosure should be or are in any single embodiment of the invention. Rather, language referring to the features and advantages is understood to mean that a specific feature, advantage, or characteristic described in connection with an embodiment is included in at least one embodiment of the subject matter disclosed herein. Thus, discussion of the features and advantages, and similar language, throughout this specification may, but do not necessarily, refer to the same embodiment.

Furthermore, the described features, advantages, and characteristics of the disclosure may be combined in any suitable manner in one or more embodiments. One skilled in the relevant art will recognize that the subject matter of the present application may be practiced without one or more of the specific features or advantages of a particular embodiment. In other instances, additional features and advantages may be recognized in certain embodiments that may not be present in all embodiments of the disclosure. Further, in some instances, well-known structures, materials, or operations are not shown or described in detail to avoid obscuring aspects of the subject matter of the present disclosure. No claim element is intended to invoke 35 U.S.C. 112(f) unless the element is expressly recited using the phrase “means for.” The scope of the disclosure is to be limited by nothing other than the appended claims, in which reference to an element in the singular is not intended to mean “one and only one” unless explicitly so stated, but rather “one or more.” It is to be understood that unless specifically stated otherwise, references to “a,” “an,” and/or “the” may include one or more than one and that reference to an item in the singular may also include the item in the plural. Further, the term “plurality” can be defined as “at least two.” As used herein, the phrase “at least one of”, when used with a list of items, means different combinations of one or more of the listed items may be used, and only one of the items in the list may be needed. The item may be a particular object, thing, or category. Moreover, where a phrase similar to “at least one of A, B, and C” is used in the claims, it is intended that the phrase be interpreted to mean that A alone may be present in an embodiment, B alone may be present in an embodiment, C alone may be present in an embodiment, or that any combination of the elements A, B and C may be present in a single embodiment; for example, A and B, A and C, B and C, or A, B, and C. In some cases, “at least one of item A, item B, and item C” may mean, for example, without limitation, two of item A, one of item B, and ten of item C; four of item B and seven of item C; or some other suitable combination.

All ranges and ratio limits disclosed herein may be combined. Unless otherwise indicated, the terms “first,” “second,” etc., are used herein merely as labels and are not intended to impose ordinal, positional, or hierarchical requirements on the items to which these terms refer. Moreover, reference to, e.g., a “second” item does not require or preclude the existence of, e.g., a “first” or lower-numbered item, and/or, e.g., a “third” or higher-numbered item.

Any reference to attached, fixed, connected, or the like may include permanent, removable, temporary, partial, full and/or any other possible attachment option. Additionally, any reference to without contact (or similar phrases) may also include reduced contact or minimal contact. In the above description, certain terms may be used, such as “up,” “down,” “upper,” “lower,” “horizontal,” “vertical,” “left,” “right,” and the like. These terms are used, where applicable, to provide some clarity of description when dealing with relative relationships. But, these terms are not intended to imply absolute relationships, positions, and/or orientations. For example, with respect to an object, an “upper” surface can become a “lower” surface simply by turning the object over. Nevertheless, it is still the same object.

Additionally, instances in this specification where one element is “coupled” to another element can include direct and indirect coupling. Direct coupling can be defined as one element coupled to and in some contact with another element. Indirect coupling can be defined as coupling between two elements not in direct contact with each other, but having one or more additional elements between the coupled elements. Further, as used herein, securing one element to another element can include direct securing and indirect securing. Additionally, as used herein, “adjacent” does not necessarily denote contact. For example, one element can be adjacent another element without being in contact with that element.

Although exemplary embodiments of the present disclosure are set forth herein, it should be appreciated that the disclosure is not so limited. For example, although reactor systems are described in connection with various specific configurations, the disclosure is not necessarily limited to these examples. Various modifications, variations, and enhancements of the system and method set forth herein may be made without departing from the spirit and scope of the present disclosure.

The subject matter of the present disclosure includes all novel and nonobvious combinations and subcombinations of the various systems, components, and configurations, and other features, functions, acts, and/or properties disclosed herein, as well as any and all equivalents thereof.

1. A method for depositing a niobium oxide containing film on a substrate in a reaction chamber, the method comprising a plurality of complete deposition cycles, each complete deposition cycle comprising:
performing a metal-oxidizer sub-cycle, wherein the metal-oxidizer sub-cycle comprises contacting the substrate with a metal precursor and a first oxygen precursor; and
performing a niobium sub-cycle, wherein the niobium sub-cycle comprises contacting the substrate with a niobium precursor.

2. The method of claim 1, wherein the niobium sub-cycle further comprises contacting the substrate with the niobium precursor and the first oxygen precursor.

3. The method of claim 2, wherein the niobium sub-cycle further comprises contacting the substrate with the niobium precursor and a second oxygen precursor different than the first oxygen precursor.

4. The method of claim 1, further comprising:
after completing the plurality of complete deposition cycles, supplying the first oxygen precursor to the reaction chamber.

5. The method of claim 4, further comprising:
after completing the plurality of complete deposition cycles, supplying a second oxygen precursor to the reaction chamber, wherein the second oxygen precursor is different than the first oxygen precursor.

6. The method of claim 1, further comprising:
removing at least one of excess precursors and reaction byproducts from the reaction chamber after at least one of contacting the substrate with the metal precursor, contacting the substrate with the first oxygen precursor, and contacting the substrate with the niobium precursor.

7. The method of claim 1, further comprising:
maintaining a deposition temperature of the reaction chamber to be less than 450°C.

8. The method of claim 1, wherein the metal precursor comprises an alkali metal, an alkaline earth metal, a transition metal, a rare-earth metal, a lanthanide metal, an actinide metal, or a post-transitional metal.

9. The method of claim 1, wherein the niobium oxide containing film comprises bismuth niobium oxide; and
wherein the metal precursor comprises a bismuth precursor comprising at least a cyclopentadienyl ligand, an amido ligand, an imido ligand, an amidinate ligand, a halide ligand, an alkyl ligand, an alkoxide ligand, a diketonate ligand, or a diazabutadiene ligand.

10. The method of claim 1, wherein the niobium oxide containing film comprises titanium niobium oxide; and
wherein the metal precursor comprises a titanium precursor comprising at least a cyclopentadienyl ligand, an amido ligand, an imido ligand, an amidinate ligand, a halide ligand, an alkyl ligand, an alkoxide ligand, a diketonate ligand, or a diazabutadiene ligand.

11. The method of claim 1, wherein the niobium oxide containing film comprises tantalum niobium oxide; and
wherein the metal precursor comprises a tantalum precursor comprising at least a cyclopentadienyl ligand, an amido ligand, an imido ligand, an amidinate ligand, a halide ligand, an alkyl ligand, an alkoxide ligand, a diketonate ligand, or a diazabutadiene ligand.

12. The method of claim 1, wherein the first oxygen precursor comprises one or more of molecular oxygen, ozone, hydrogen peroxide, water, formic acid, nitrous oxide, nitrogen oxide, or dinitrogen pentoxide.

13. The method of claim 1, wherein the niobium precursor comprises at least a cyclopentadienyl ligand, an amido ligand, an imido ligand, an amidinate ligand, a halide ligand, an alkyl ligand, an alkoxide ligand, a diketonate ligand, or a diazabutadiene ligand.

14. The method of claim 1, wherein the niobium oxide containing film comprises BiNbO₄.

15. The method of claim 1, wherein the niobium oxide containing film comprises a dielectric constant between 30 and 250.

16. A reactor, comprising:
a reaction chamber for supporting a substrate;
a metal source connected to the reaction chamber and configured to provide a metal precursor;
a niobium source connected to the reaction chamber and configured to provide a niobium precursor;
a first oxygen source connected to the reaction chamber and configured to provide a first oxygen precursor; and
a control system configured to control the reactor to perform a plurality of complete deposition cycles to deposit a niobium oxide containing film on the substrate, wherein each complete deposition cycle comprises:
a metal-oxidizer sub-cycle comprising supplying, to the reaction chamber, the metal precursor from the metal source and the first oxygen precursor from the first oxygen source; and
a niobium sub-cycle comprising by supplying, to the reaction chamber, the niobium precursor from the niobium source.

17. The reactor of claim 16, wherein the niobium sub-cycle further comprises supplying, to the reaction chamber, the niobium precursor from the niobium source and the first oxygen precursor from the first oxygen source.

18. The reactor of claim 16, further comprising:
a second oxygen source connected to the reaction chamber and configured to provide a second oxygen precursor different than the first oxygen precursor,
wherein the niobium sub-cycle further comprises supplying, to the reaction chamber, the niobium precursor from the niobium source and the second oxygen precursor from the second oxygen source.

19. The reactor of claim 16, wherein the control system is further configured to control the reactor to supply, after completing the plurality of complete deposition cycles, the first oxygen precursor from the first oxygen source to the reaction chamber.

20. The reactor of claim 16, further comprising:
a second oxygen source connected to the reaction chamber and configured to provide a second oxygen precursor different than the first oxygen precursor,
wherein the control system is further configured to control the reactor to supply, after completing the plurality of complete deposition cycles, the second oxygen precursor from the second oxygen source to the reaction chamber.
